(19) United States
(12) Patent Application Publication
(10) Pub. No.: US 2017/0058395 A1
(43) Pub. Date: Mar. 2, 2017

(54) Removing Device for Removing Evaporated Material and Evaporation Device

(71) Applicant: BOE TECHNOLOGY GROUP CO., LTD., Beijing (CN)

(72) Inventor: Peng ZHANG, Beijing (CN)

(73) Assignee: BOE TECHNOLOGY GROUP CO., LTD., Beijing (CN)

(21) Appl. No.: 15/094,307

(22) Filed: Apr. 8, 2016

(30) Foreign Application Priority Data
Sep. 1, 2015 (CN) 201510552509.1

(51) Int. Cl. C23C 14/22; H01L 51/00; H01L 51/56; H01L 21/67; C23C 14/54; B08B 1/00

(52) U.S. Cl. CPC C23C 14/22; C23C 14/54; B08B 1/001; H01L 51/56; H01L 21/67288; H01L 51/0008

(57) ABSTRACT

The present disclosure provides a device for removing an evaporated material and an evaporation device. The removing device includes a shutter arranged above an evaporation source, a movement member configured to control the shutter to move in both a horizontal direction and a vertical direction relative to the evaporation source, a motor arranged on the shutter, and a removing member connected to, and driven by, the motor, and configured to remove the evaporated material deposited at and blocking an outlet of the evaporation source.

### CROSS-REFERENCE TO RELATED APPLICATION

The present application claims a priority of the Chinese patent application No. 201510552509.1 filed on Sep. 1, 2015, which is incorporated herein by reference in its entirety.

### TECHNICAL FIELD

The present disclosure relates to the field of display technology, in particular to a removing device for removing an evaporated material and an evaporation device.

### BACKGROUND

In recently years, organic light-emitting diode (OLED) display devices have become more and more popular at home and abroad. As compared with a liquid crystal display (LCD) which is currently a main flat-panel display device, the OLED display device has such advantages as self-luminescence, wide viewing angle (more than 175°), short response time (1 μs), wide color gamut, low operating voltage (3-10V), small thickness, being flexible and wide operating temperature range. Although the OLED display technology is not so mature as compared with the other display technologies, it may become, along with its development, a mainstream technology for the display devices in future.

Among OLED elements, a top-emission OLED element is obviously superior to a bottom-emission OLED element in terms of color purity, efficiency, aperture ratio and etc. However, there is an obvious microcavity effect for the top-emission OLED element, and when the microcavity effect cannot be controlled appropriately, the light intensity and color of the OLED element may change along with a viewing angle. The microcavity effect will be described hereinafter briefly.

The microcavity effect refers to optical interference among components of the element, and it exists in both the top-emission OLED element and the bottom-emission OLED element, more or less. Principally, the microcavity effect refers to a situation where photons in different energy states are re-distributed in such a manner that merely a light beam at a particular wavelength can be emitted at a particular angle after a microcavity mode is satisfied. At this time, a full width at half maximum (FWHM) of an optical wave may be narrowed, and the light intensities and visual effects may be different at different viewing angles. For the bottom-emission OLED element, its anode is transparent and has very large light transmittance, so the microcavity effect is not obvious. However, for the top-emission OLED element, its anode is made of indium tin oxide (ITO) having very large reflectivity, and its cathode is usually a translucent metal film. With this translucent cathode, the light reflection will increase, thereby the interference of photon beams may occur between the anode and the cathode (this interference belongs to wide-angle interference) and the microcavity effect may become more obvious. For the OLED element, a top-emission structure is usually adopted due to its advantages in efficiency, color purity, aperture ratio and etc. However, the light intensity and the viewing angle may be adversely affected by the strong microcavity effect, so the color of an image displayed by the OELD display device may change along with the viewing angle.

Hence, for the top-emission OLED element, how to use and control the microcavity effect becomes a very important topic. A film thickness of the entire microcavity is a critical factor that may adversely affect the luminescent property. During the evaporation of the top-emission OLED element using a crucible to form organic layers thereon, when an organic material deposited at and blocking an outlet of the crucible is not removed in time, a film thickness detected by a crystal oscillator sheet is different from an actual thickness of the film formed by evaporation, and it is unable to accurately control the film thickness of the microcavity of the top-emission OLED element. In this regard, there is an urgent need to remove the organic material deposited at and blocking the outlet of the crucible in time, so as to accurately control the film thickness of the microcavity.

### SUMMARY

A main object of the present disclosure is to provide a device for removing an evaporated material and an evaporation device, so as to remove an organic material deposited at and blocking an outlet of an evaporation source, e.g., a crucible, in time, thereby to accurately control a film thickness of a microcavity and improve the luminescent property of a top-emission element.

In one aspect, the present disclosure provides a removing device for removing an evaporated material, including a shutter arranged above an evaporation source, a movement member configured to control the shutter to move in both a horizontal direction and a vertical direction relative to the evaporation source, a motor arranged on the shutter, and a removing member connected to, and driven by, the motor, and configured to remove the evaporated material deposited at and blocking an outlet of the evaporation source.

Alternatively, the removing member is a drill bit.

Alternatively, the drill bit is of a conical shape.

Alternatively, a bottom surface of the conical drill bit has a diameter of 0.5 cm to 3 cm.

Alternatively, the diameter of bottom surface of the conical drill bit matches a diameter of the outlet of the evaporation source.

Alternatively, a material of the drill bit includes a ceramic material.

Alternatively, the removing device further includes a metallic cover arranged at a lower surface of the shutter and surrounding the motor and the removing member, so as to prevent the evaporated material removed by the removing member from entering an evaporation cavity.

In another aspect, the present disclosure provides in some embodiments an evaporation device, including an evaporation cavity, an evaporation source arranged in the evaporation cavity, a small shutter configured to shield or reveal an outlet of the evaporation source, and the above-mentioned removing device.

Alternatively, the evaporation device further includes a monitoring member configured to monitor whether or not an evaporated material is deposited at and blocking the outlet of the evaporation source in the evaporation cavity, and when the evaporated material is deposited at and blocking the outlet of the evaporation source, enable the removing device to remove the evaporated material.

Alternatively, the evaporation device further includes a malfunction handling member configured to detect an operating state of the small shutter, and when a malfunction happens, enable the removing device to shield or reveal the outlet of the evaporation source.

According to the device for removing the evaporated material and the evaporation device in the embodiments of the present disclosure, it is able to remove the organic material deposited at and blocking the outlet of the evaporation source in time as compared with the related art, thereby to ensure a film thickness detected by the crystal oscillator sheet to be identical to an actual thickness of a film formed on the substrate by the evaporation, and to accurately control the film thickness of the microcavity of the OLED element.

### BRIEF DESCRIPTION OF THE DRAWINGS

In order to illustrate the technical solutions of the present disclosure or the related art in a clearer manner, the drawings desired for the present disclosure or the related art will be described hereinafter briefly. Obviously, the following drawings merely relate to some embodiments of the present disclosure, and based on these drawings, a person skilled in the art may obtain the other drawings without any creative effort.

FIG. 1 is a sectional view of a device for removing an evaporated material according to one embodiment of the present disclosure; and

FIG. 2 is a schematic view showing positions of the removing device and small shutters relative to an outlet of an evaporation source according to one embodiment of the present disclosure.

### DETAILED DESCRIPTION OF THE EMBODIMENTS

In order to make the objects, the technical solutions and the advantages of the present disclosure more apparent, the present disclosure will be described hereinafter in a clear and complete manner in conjunction with the drawings and embodiments. Obviously, the following embodiments merely relate to a part of, rather than all of, the embodiments of the present disclosure, and based on these embodiments, a person skilled in the art may, without any creative effort, obtain the other embodiments, which also fall within the scope of the present disclosure.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “a” are merely used to represent the existence of at least one member, rather than to limit the number thereof. Such words as “connect” or “connected to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

A main object of the present disclosure is to provide a scheme so as to accurately control a thickness of each organic film formed by the evaporation, thereby to ensure an even film thickness of a microcavity formed by different components.

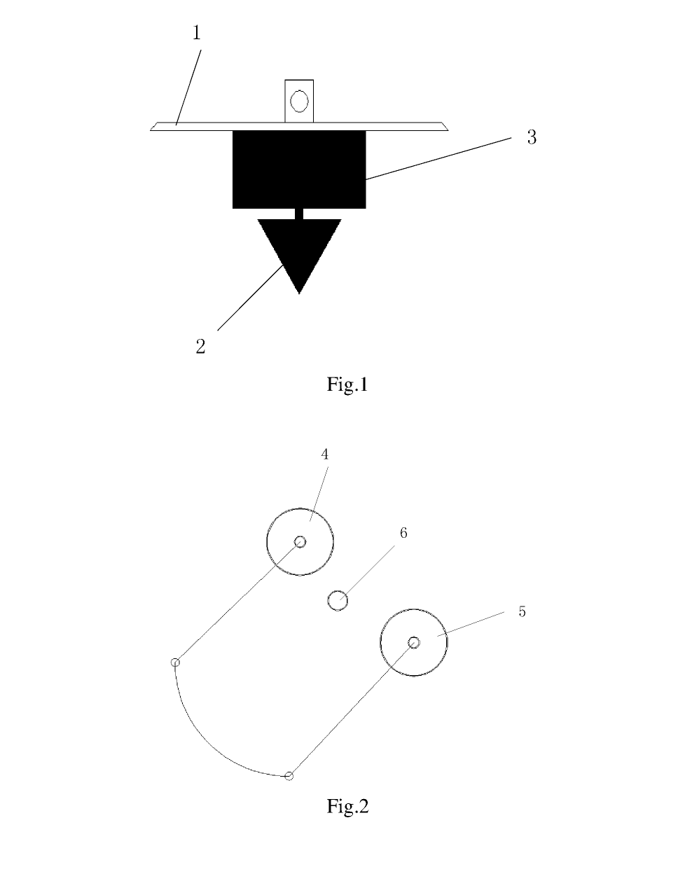

In order to achieve the above object, the present disclosure provides in some embodiments a removing device for removing an evaporated material. Referring to FIG. 1, which is a sectional view of the removing device according to one embodiment of the present disclosure, the removing device may include a shutter 1 arranged above an evaporation source, a movement member (not shown) configured to control the shutter 1 to move in both a horizontal direction and a vertical direction relative to the evaporation source, a motor (not shown) arranged on the shutter 1, and a removing member 2 connected to, and driven by, the motor, and configured to remove the evaporated material deposited at and blocking an outlet of the evaporation source.

During the actual application, the removing device may be obtained by improving an existing small shutter or source shutter used in an OLED evaporation process.

For the evaporation process, the small shutter arranged at an upper portion of the evaporation source is indispensable, and an evaporation speed of the evaporation source may be detected by a quartz crystal microbalance (QCM) sensor only when the small shutter is moved away so as to allow the organic material heated by a heat source and reaching a certain temperature to escape from the evaporation source. In the related art, usually, the small shutter is arranged at one side and above the outlet of the evaporation source, and when it is required to close the evaporation resource, the small shutter is moved to be directly below the outlet of the evaporation source, so as to shield the outlet of the evaporation source and stop the evaporation of the organic material. During the evaporation, the small shutter merely functions as to close and open the evaporation source.

In the embodiments of the present disclosure, a further small shutter may be arranged at another side and above the outlet of the evaporation source and serve as the shutter for the removing device, and then the motor and the removing member may be arranged on the further small shutter.

In other words, in the embodiments of the present disclosure, two small shutters are arranged at two sides and above the outlet of the evaporation source respectively. One of them is the existing small shutter, and the other is just the shutter of the removing device, on which the motor and the removing member are arranged. FIG. 2 shows positions of the removing device and the small shutters relative to the outlet of the evaporation source, where 4 represents the existing small shutter, 5 represents the shutter of the removing device, and 6 represents the outlet of the evaporation source.

As is known in the art, the movement member may be arranged in various ways. Obviously, in order to simply the entire structure, a known movement mechanism for moving the small shutter may be used to move the shutter of the removing device. Under the control of the movement member, it is able to move the removing device in both the horizontal direction and the vertical direction, and to control the movement of the removing device precisely, thereby to prevent the evaporation source (e.g., a crucible) from being pressed.

In the embodiments of the present disclosure, the removing member 2 may be a drill bit. During the actual application, the drill bit may be of any of various shapes, e.g., a pyramid shape such as a triangular pyramid shape or a rectangular pyramid shape, a conical shape, or even a triangular sheet-like shape. Although the triangular sheet-like structure has merely two ridges, it may also function as a drill bit when it is rotated. Alternatively, the drill bit is of a conical shape which has a structure of being wide at the top and being narrow at the bottom, so as to effectively remove the organic material deposited at both a center and an edge of the outlet of the evaporation source (e.g., the crucible). Obviously, the shapes of the removing member in the embodiments of the present disclosure are not limited thereto.

For the existing evaporation process, the outlet of the evaporation source may be in any of various diameters. In order to improve a removing effect, in the embodiments of the present disclosure, a size of the conical drill bit needs to approach to the diameter of the outlet of the evaporation source as much as possible, i.e., it is necessary to ensure that a diameter of a bottom surface of the conical drill bit matches the diameter of the outlet of the evaporation source. Thus, in the embodiments of the present disclosure, the diameter of the bottom surface of the conical drill bit may be in a range between 0.5 cm and 3 cm, so as to meet the actual requirement on removing the deposited organic material to a great extent.

In the embodiments of the present disclosure, a material of the drill bit may include a ceramic material. The ceramic material has a high hardness and may not be deformed due to friction during the rotation of the drill bit. In addition, the ceramic material has stable properties, and thus one ceramic drill bit may be provided for one kind of evaporated material, so as to prevent the pollution generated between different evaporated materials (for example, the organic material, etc).

In the embodiments of the present disclosure, the removing device further includes a metallic cover 3 arranged at a lower surface of the shutter 1 and surrounding the motor and the removing member 2 (in FIG. 1, the motor is shielded by the metallic cover 3), so as to prevent the evaporated material removed by the removing member 2 from entering an evaporation cavity. The metallic cover 3 may shield the motor and the drill bit no matter whether the removing device is in an operating state or an idle state. In this way, it is able to prevent the motor and the drill bit from being polluted, and to prevent the entire evaporation environment from being polluted when the organic material removed by the drill bit enters the evaporation cavity.

In the embodiments of the present disclosure, the removing device is formed by integrating the motor with the drill bit onto the small shutter, and the drill bit is of a conical shape. In this way, it is able to effectively remove not only the organic material deposited at the center of the outlet of the evaporation source (e.g., the crucible), but also the organic material deposited at the edge of the outlet of evaporation source when the drill bit moves downward. In addition, a rotation speed of the drill bit may be controlled by changing the power supplied to the motor, i.e., a drilling rate of the drill bit is adjustable with respect to different evaporated materials and different deposition situations. As a result, it is able to accurately control a film thickness of the microcavity of the top-emission OLED element.

The present disclosure further provides in some embodiments an evaporation device, which may include an evaporation cavity, an evaporation source arranged in the evaporation cavity, a small shutter configured to shield or reveal an outlet of the evaporation source, and the above-mentioned removing device.

In the embodiments of the present disclosure, the evaporation device may further include a monitoring member configured to monitor whether or not an evaporated material is deposited at and blocking the outlet of the evaporation source in the evaporation cavity, and when the evaporated material is deposited at and blocking the outlet of the evaporation source, enable the removing device to remove the evaporated material.

In the embodiments of the present disclosure, the evaporation device may further include a malfunction handling member configured to detect an operating state of the small shutter, and when a malfunction happens, enable the removing device to shield or reveal the outlet of the evaporation source.

In other words, the above removing device may also function as the small shutter of the evaporation device. When the small shutter fails to properly close, the removing device may temporarily function as the small shutter and move to be above the outlet of the evaporation source, so as to shield the outlet and ensure the normal evaporation. After the evaporation is completed, a door of the evaporation cavity may be opened so as to remove the organic material deposited at and blocking the outlet of the evaporation source, e.g., the crucible.

According to the embodiments of the present disclosure, the thick of the evaporated organic layer may be effectively improved, and it is able to remove the organic material deposited at and blocking the outlet of the evaporation source, e.g., the crucible, in time, thereby to ensure the film thickness detected by the crystal oscillator sheet to be identical to an actual thickness of the film formed on the substrate by the evaporation, and to accurately control the film thickness of the microcavity of the OLED element.

The above are merely the preferred embodiments of the present disclosure. It should be appreciated that, a person skilled in the art may make further modifications and improvements without departing the principle of the present disclosure, and these modifications and improvements shall also fall within the scope of the present disclosure.

What is claimed is:

1. A removing device for removing an evaporated material, comprising:
a shutter arranged above an evaporation source;
a movement member configured to control the shutter to move in both a horizontal direction and a vertical direction relative to the evaporation source;
a motor arranged on the shutter; and
a removing member connected to, and driven by, the motor, and configured to remove the evaporated material deposited at and blocking an outlet of the evaporation source.

2. The removing device according to claim 1, wherein the removing member is a drill bit.

3. The removing device according to claim 2, wherein the drill bit is of a conical shape.

4. The removing device according to claim 3, wherein a bottom surface of the conical drill bit has a diameter of 0.5 cm to 3 cm.

5. The removing device according to claim 4, wherein the diameter of the bottom surface of the conical drill bit matches a diameter of the outlet of the evaporation source.

6. The removing device according to claim 2, wherein a material of the drill bit comprises a ceramic material.

7. The removing device according to claim 1, further comprising:
a metallic cover arranged at a lower surface of the shutter and surrounding the motor and the removing member, so as to prevent the evaporated material removed by the removing member from entering an evaporation cavity.

8. The removing device according to claim 2, further comprising:
a metallic cover arranged at a lower surface of the shutter and surrounding the motor and the removing member, so as to prevent the evaporated material removed by the removing member from entering an evaporation cavity.

9. The removing device according to claim 6, further comprising:
a metallic cover arranged at a lower surface of the shutter and surrounding the motor and the removing member, so as to prevent the evaporated material removed by the removing member from entering an evaporation cavity.

10. An evaporation device, comprising:
an evaporation cavity;
an evaporation source arranged in the evaporation cavity;
a small shutter configured to shield or reveal an outlet of the evaporation source; and
the removing device according to claim 1.

11. The evaporation device according to claim 10, wherein the removing member is a drill bit.

12. The evaporation device according to claim 11, wherein the drill bit is of a conical shape.

13. The evaporation device according to claim 12, wherein a bottom surface of the conical drill bit has a diameter of 0.5 cm to 3 cm.

14. The evaporation device according to claim 13, wherein the diameter of the bottom surface of the conical drill bit matches a diameter of the outlet of the evaporation source.

15. The evaporation device according to claim 11, wherein a material of the drill bit comprises a ceramic material.

16. The evaporation device according to claim 10, wherein the removing device further comprises:
a metallic cover arranged at a lower surface of the shutter and surrounding the motor and the removing member, so as to prevent the evaporated material removed by the removing member from entering an evaporation cavity.

17. The evaporation device according to claim 11, wherein the removing device further comprises:
a metallic cover arranged at a lower surface of the shutter and surrounding the motor and the removing member, so as to prevent the evaporated material removed by the removing member from entering an evaporation cavity.

18. The evaporation device according to claim 10, further comprising:
a monitoring member configured to monitor whether or not an evaporated material is deposited at and blocking the outlet of the evaporation source in the evaporation cavity, and enable the removing device to remove the evaporated material when the monitoring member monitors that the evaporated material is deposited at and blocking the outlet of the evaporation source.

19. The evaporation device according to claim 10, further comprising:
a malfunction handling member configured to detect an operating state of the small shutter, and enable the removing device to shield or reveal the outlet of the evaporation source when the malfunction handling member detects that the small shutter fails to operate properly.

20. The evaporation device according to claim 18, further comprising:
a malfunction handling member configured to detect an operating state of the small shutter, and enable the removing device to shield or reveal the outlet of the evaporation source when the malfunction handling member detects that the small shutter fails to operate properly.
